(19) United States
(12) Patent Application Publication
(10) Pub. No.: US 2014/0138839 A1
(43) Pub. Date: May 22, 2014

(54) POWER SEMICONDUCTOR MODULE

(71) Applicant: SAMSUNG ELECTRO-MECHANICS CO., LTD., Suwon (KR)

(72) Inventors: Job Ha, Suwon (KR); Sang Hee Park, Suwon (KR)

(73) Assignee: SAMSUNG ELECTRO-MECHANICS CO., LTD., Suwon (KR)

(21) Appl. No.: 13/735,125

(22) Filed: Jan. 7, 2013

(30) Foreign Application Priority Data
Nov. 20, 2012 (KR) 10-2012-0131687

(51) Int. Cl. H01L 23/48

(52) U.S. Cl. CPC H01L 23/48
USPC 257/773

(57) ABSTRACT

Disclosed herein is a power semiconductor module including a substrate having a first metal conductive track formed on one surface thereof, and a base plate made of a metal and solder-joined to the substrate in the first metal conductive track region, wherein a first uneven pattern is formed in the solder junction region formed between the substrate and the base plate.

### CROSS REFERENCE TO RELATED APPLICATION

This application claims the benefit of Korean Patent Application No. 10-2012-0131687, filed on Nov. 20, 2012, entitled “Power Semiconductor Module”, which is hereby incorporated by reference in its entirety into this application.

### BACKGROUND OF THE INVENTION

1. Technical Field

The present invention relates to a power semiconductor module.

2. Description of the Related Art

A power semiconductor module modularizes a power semiconductor such as an insulated gate bipolar mode transistor (IGBT), a metal oxide semi-conductor field effect transistor (MOSFET), or the like. Power semiconductor achieves high breakdown voltage characteristics, high current characteristics, and high frequency characteristics in comparison to a general semiconductor.

The power semiconductor module is classified into a high power application and a low power application. For a high power application, a plurality of semiconductor elements is mounted on a substrate.

Here, a ceramic substrate such as an aluminum oxide (Al₂O₃) substrate, a boron nitride (BN) substrate, an aluminum nitride (AlN) substrate, a silicon oxide (SiO2) substrate, or the like, may be used.

Currently, most high power semiconductor modules use a direct bonded copper (DBC) substrate or a direct bonded aluminum (DBA) substrate having a metal (Cu, Al, or the like) conductive track formed on a single surface of both surfaces thereof.

In order for a ceramic substrate to be applied for industrial purposes or to electrical apparatuses, the ceramic substrate is required to be resistant to mechanical shock or impact and stably assembled with a heat dissipation system as well.

In order to provide mechanical rigidity to a ceramic substrate, the ceramic substrate is solder-joined with a metal base plate using copper (Cu) or aluminum (Al) so as to be used to fabricate a power semiconductor module.

Here, in order to secure long-term reliability of the power semiconductor module, electrical wire interconnection is critical in an electrical aspect and a joint state of a solder joint is critical in a thermal aspect.

Meanwhile, a generally well-known typical housing-type power semiconductor module has a structure including at least two solder joint layers.

One of the solder junction layers is a junction between a power semiconductor, i.e., a semiconductor element, and a substrate, and the other is a junction between a substrate and a base plate.

In such a junction structure, the solder junction region between the substrate and the base plate is most vulnerable to crack. Of course, the solder junction region is also vulnerable to crack.

If cracks propagate along the solder junction region, heat generated during a switching operation of a semiconductor element cannot easily released to a heat sink, so reliability of the solder junction region is very important in the power semiconductor module.

In general, a base plate has a smooth surface in which a region soldered with a substrate and regions other than the soldered region are not discriminated.

Of course, in order to prevent solder from being excessively spread, a solder resist pattern may be formed along a boundary to which a substrate is joined, but the base plate generally has a flat surface overall.

When solder-joined with a large substrate, the smooth flat surface of the base plate may have the following problems.

First, during a soldering process, a solder flow on a smooth, uniform interface between the substrate and the base plate may sequentially proceed toward an outer side of the substrate along the plane, so a flux gas generated from a central portion of the substrate may not be discharged to the outer side of the substrate, generating a non-junction portion or a void.

Second, cracks may be formed in a solder junction region between the substrate and the base plate due to a difference between coefficients of thermal expansion of the substrate and the base plate according to a rapid change in temperature. In this case, the smooth, uniform interface between the substrate and the base plate causes cracks propagate faster, degrading long-term reliability of the power semiconductor module.

### PRIOR ART DOCUMENT

### Patent Document

(Patent Document 1) Korean Patent Laid-Open Publication No. 10-2006-0092687

### SUMMARY OF THE INVENTION

The present invention has been made in an effort to provide a power semiconductor module in which a flux gas generated from a central portion of a substrate during a process of soldering a substrate and a base plate is easily discharged to the outside of the substrate, thus restraining a generation of a non-junction portion or a void, and a speed at which cracks propagate in a solder junction region is considerably slowed relative to the related art through structural stabilization, thus obtaining long-term reliability.

According to a preferred embodiment of the present invention, there is provided a power semiconductor module including: a substrate having a first metal conductive track formed on one surface thereof; and a base plate made of a metal and solder-joined to the substrate in the first metal conductive track region, wherein a first uneven pattern is formed in the solder junction region formed between the substrate and the base plate.

The first uneven pattern may be formed on at least one of the first metal conductive track and the base plate.

The first uneven pattern may be formed to have different shapes and different sizes over the entire surface region of the first metal conductive track or the base plate.

The first uneven pattern may be formed to have different shapes and different sizes over a part of the regions of the surface of the first metal conductive track or the base plate.

The first uneven pattern may be formed to have the same shape and same size over the entire surface region of the first metal conductive track or the base plate.

The first uneven pattern may be formed over a part of the regions of the surface of the first metal conductive track or the base plate.

A second metal conductive track may be formed on the other surface of the substrate, a semiconductor element may be mounted on the second metal conductive track, and a second uneven pattern may be formed in a solder junction region formed between the substrate and the semiconductor element.

The second uneven pattern may be formed on the second metal conductive track.

The second uneven pattern may be formed to have different shapes or sizes over the entire surface region of the surface of the second metal conductive track or over a part of the regions of the surface of the second metal conductive track.

The second uneven pattern may be formed to have the same shape and same size over the entire surface region of the surface of the second metal conductive track or over a part of the regions of the surface of the second metal conductive track.

The first and second uneven patterns may have a circular, quadrangular, or triangular shape, and may be formed to be concave or convex on the corresponding surface.

A heat sink may be coupled to the base plate, and the substrate may be a direct bonded copper (DBC) ceramic substrate or a direct bonded aluminum (DBA) ceramic substrate.

### BRIEF DESCRIPTION OF THE DRAWINGS

The above and other objects, features, and advantages of the present invention will be more clearly understood from the following detailed description taken in conjunction with the accompanying drawings, in which:

FIG. 1 is a view illustrating a power semiconductor module according to a first embodiment of the present invention;

FIG. 2 is a plan view of a base plate illustrated in FIG. 1;

FIG. 3 is a view illustrating a lateral structure of FIG. 2;

FIG. 4 is a view illustrating a power semiconductor module according to a second embodiment of the present invention;

FIG. 5 is a view illustrating a power semiconductor module according to a third embodiment of the present invention;

FIG. 6 is a view illustrating a power semiconductor module according to a fourth embodiment of the present invention;

FIGS. 7 to 11 are modifications of first uneven patterns on base plates, respectively; and

FIGS. 12 to 14 are modifications of second uneven patterns on second metal conductive tracks of substrates, respectively.

### DESCRIPTION OF THE PREFERRED EMBODIMENTS

The objects, features, and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side”, and the like, are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

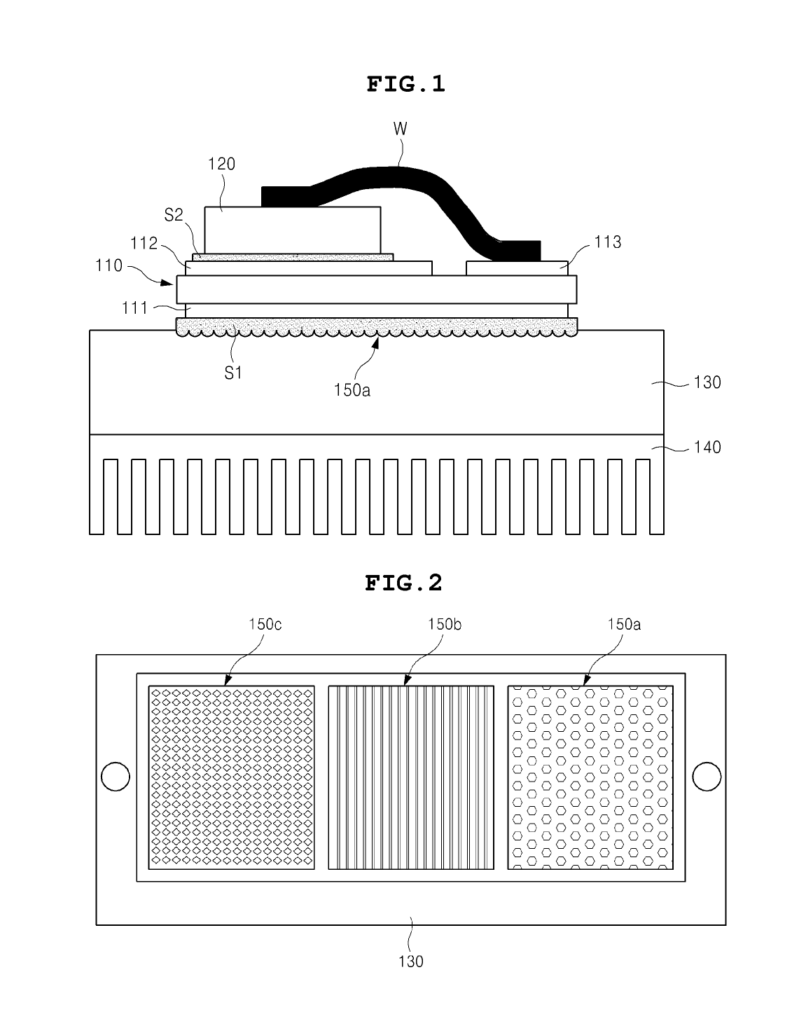

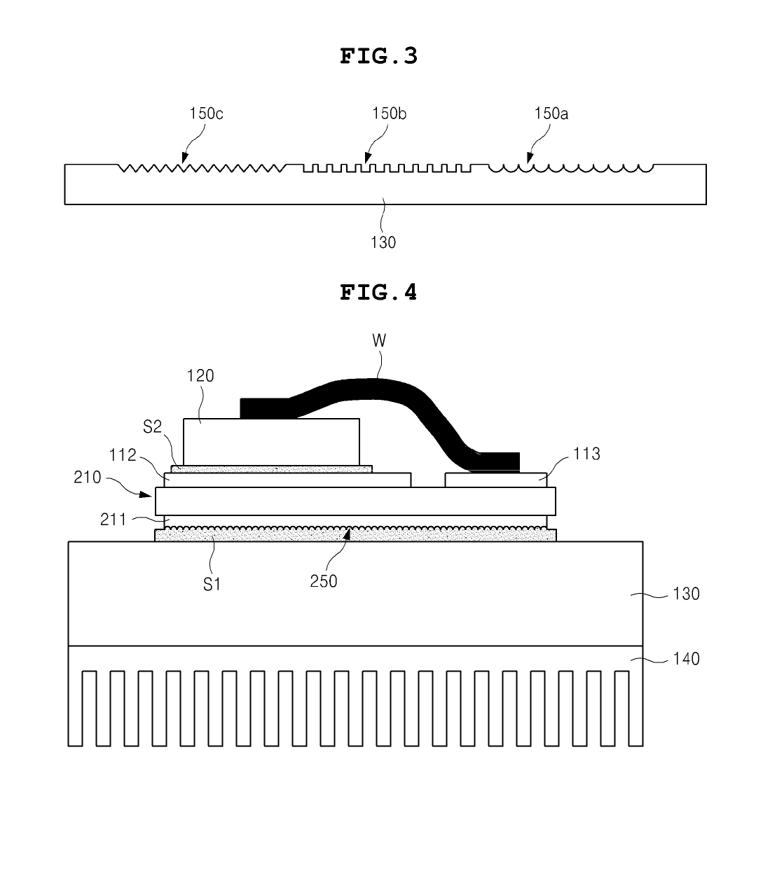

FIG. 1 is a view illustrating a power semiconductor module according to a first embodiment of the present invention. FIG. 2 is a plan view of a base plate illustrated in FIG. 1. FIG. 3 is a view illustrating a lateral structure of FIG. 2.

Referring to FIGS. 1 to 3, a power semiconductor module according to the present embodiment aims at a high power application, having a structure in which a plurality of semiconductor elements 120 is mounted on a substrate 110. FIG. 1 illustrates a single semiconductor element 120, but it is merely an example and a plurality of semiconductor elements 120 may be formed on the substrate 110 to form the power semiconductor module.

In detail, the power semiconductor module according to an embodiment of the present invention includes the substrate 110 having a first metal conductive track 111 formed on one surface (i.e., a lower surface) thereof and a base plate 130 made of a metal and solder-joined with the substrate 110 in the metal conductive track 111 region.

Second metal conductive tracks 112 and 113 are provided on the other surface (i.e., an upper surface) of the substrate 110. The foregoing semiconductor element 120 may be mounted on the second metal conductive track 112.

In the present embodiment, the substrate 110 may be a direct bonded copper (DBC) ceramic substrate or a direct bonded aluminum (DBA) ceramic substrate, and in this case, as mentioned above, the first metal conductive track 111 and the second metal conductive tracks 112 and 113 may be provided on both sides thereof. The first metal conductive track 111 and the second metal conductive tracks 112 and 113 may be made of copper (Cu), aluminum (Al), or the like.

Of course, unlike the illustration, only the first metal conductive track 111 may be formed to be joined with the base plate 130 and such a substrate also belongs to the scope of the present invention.

The substrate 110 and the semiconductor element 120 may be joined by wire bonding (W) or soldering S2 as illustrated in FIG. 1.

The base plate 130 is a structure joined with the substrate 110 in order to secure mechanical rigidity of the foregoing substrate 110. The base plate 130 may also be made of a metal such as copper (Cu), aluminum (Al), or the like.

A heat sink 140 for dissipating heat is coupled to the base plate 130.

Meanwhile, first uneven patterns (i.e., first concavo-convex patterns, first depression and protrusion patterns, or first irregular patterns) 150a to 150c are formed on a solder (S1) junction region formed between the substrate 110 and the base plate 130.

The first uneven patterns 150a to 150c may be formed on the first metal conductive track 111 or the base plate 130. In the present embodiment, for example, the first uneven patterns 150a to 150c are formed on the base plate 130.

Here, the first uneven patterns 150a to 150c may be formed to have different shapes and different sizes over the entire surface regions of the base plate 130 as illustrated in FIG. 2. This means that a plurality of substrates 110 is joined on the base plate 130.

As illustrated in FIGS. 2 and 3, the first uneven patterns 150a to 150c may have a circular, quadrangular, or triangular shape, and may be provided as concave type patterns at corresponding positions. When the first uneven patterns 150a to 150c are formed to have different shapes and different sizes on the entire surface regions of the base plate 130 as illustrated in FIG. 2, flow characteristics of the solder S1 or flux gas may be changed.

Of course, the first uneven patterns 150a to 150c may have various shapes including horizontal patterns, vertical patterns, oblique patterns, lattice patterns, other than the illustrated ones, and may be implemented according to a method such as notch, dimple, groove processing, or the like.

A processing depth of the first uneven patterns 150a to 150c may be appropriately designed in consideration of a thickness of the first metal conductive track 111 or the base plate 130 and soldering characteristics. In the present embodiment, the first uneven patterns 150a to 150c may be formed to have an area larger than that of the substrate 110.

Of course, unlike the case of FIG. 2, the first uneven patterns 150a to 150c may be formed to have different shapes and different sizes in portion to the first metal conductive track 111 or the surface of the base plate 130.

The presence of the first uneven patterns 150a to 150c formed on the surface of the base plate 130 provides the following excellent effect.

First, during a soldering process performed between the substrate 110 and the base plate 130, a flux gas generated from a central portion of the substrate 110 may be easily discharged to the outside of the substrate 110 owing to the first uneven patterns 150a to 150c, preventing a generation of a non-junction portion or a void.

Second, cracks may occur in the solder S1 junction region between the substrate 110 and the base plate 130 due to a difference in coefficients of thermal expansion according to a rapid change in temperature; however, since the first uneven patterns 150a to 150c are formed between the substrate 110 and the base plate 130, a crack propagation speed in the solder S1 junction region can be drastically lowered owing to structural stabilization, in comparison to the related art, thus obtaining long-term reliability in the power semiconductor module.

FIG. 4 is a view illustrating a power semiconductor module according to a second embodiment of the present invention.

FIG. 4 shows a case in which a first uneven pattern 250 is formed on a surface of a first metal conductive track 211 of a substrate 210.

Also, in this case, the first uneven pattern 250 may be formed to have different shapes or different sizes or the same shape or size over the entire surface region or in a part of a region of the first metal conductive track 211.

When this structure is employed, a flux gas generated from a central portion of the substrate 210 can be easily discharged to the outside of the substrate 210 during a soldering process performed between the substrate 210 and the base plate 130, a generation of a non-junction portion or a void can be restrained, and a crack propagation speed in the solder S1 junction region can be drastically lowered due to the structural stabilization, in comparison to the related art, thus obtaining long-term reliability in the power semiconductor module.

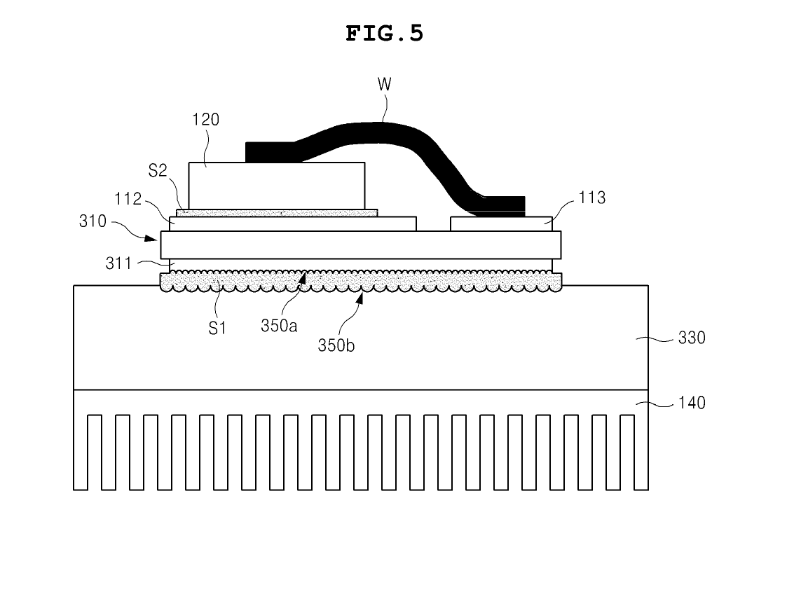

FIG. 5 is a view illustrating a power semiconductor module according to a third embodiment of the present invention.

FIG. 5 shows a case in which first uneven patterns 350a and 350b are formed on both surfaces of a first metal conductive track 311 of a substrate 310 and a base plate 330. In other words, the first uneven patterns 350a and 350b may be formed as a combination of the patterns of FIGS. 1 and 4.

In this case, the first uneven pattern 350a formed on the surface of first metal conductive track 311 may be finer than the first uneven patterns 350b formed on the surface of the base plate 330, but it may not necessarily do.

When this structure is employed, a flux gas generated from a central portion of the substrate 310 can be easily discharged to the outside of the substrate 310 during a soldering process performed between the substrate 310 and the base plate 330, a generation of a non-junction portion or a void can be restrained, and a crack propagation speed in the solder S1 junction region can be drastically lowered due to the structural stabilization, in comparison to the related art, thus obtaining long-term reliability in the power semiconductor module.

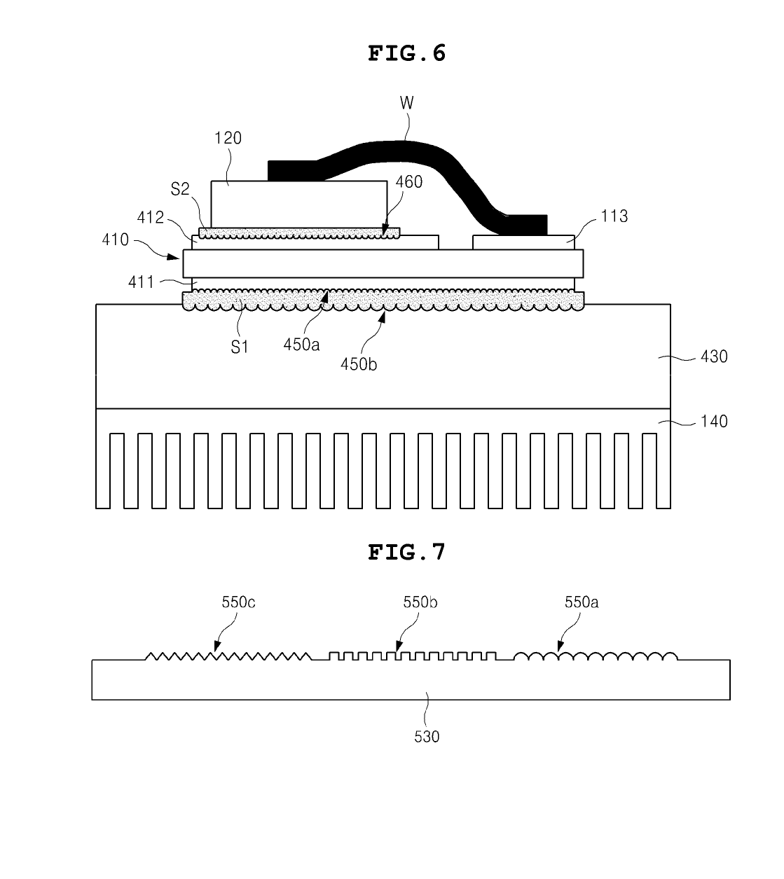

FIG. 6 is a view illustrating a power semiconductor module according to a fourth embodiment of the present invention.

Like the case of FIG. 5, FIG. 6 shows a case in which first uneven patterns 450a and 450b are formed on both surfaces of a first metal conductive track 411 of a substrate 410 and a base plate 430.

However, in the present embodiment, a second uneven pattern 460 is additionally formed on a surface of a second metal conductive track 412.

Like the first uneven patterns 450a and 450b, the second uneven pattern 460 may be formed to have different shapes or sizes or may be formed to have the same shape and same size over the entire surface region or over a part of a region of the second metal conductive track 412. The second uneven pattern 460 may also have a concave or convex structure.

When this structure is employed, a flux gas generated from a central portion of the substrate 410 can be easily discharged to the outside of the substrate 410 during a soldering process performed between the substrate 410 and the base plate 430, a generation of a non-junction portion or a void can be restrained, and a crack propagation speed in the solder S1 junction region can be drastically lowered due to the structural stabilization, in comparison to the related art, thus obtaining long-term reliability in the power semiconductor module.

Besides, in the present embodiment, since the second uneven pattern 460 is additionally formed on the surface of the second metal conductive track 412 of the substrate 410, the flux gas generated from the central portion of the substrate 410 can be easily discharged to the outside of the substrate 410 during a soldering process performed between the substrate 410 and the semiconductor element 120, restraining a generation of a non-junction portion or a void.

FIGS. 7 to 11 are modifications of first uneven patterns on base plates, respectively.

FIG. 7 shows a case in which first uneven patterns 550a and 550b formed on the surface of the base plate 430 are convex.

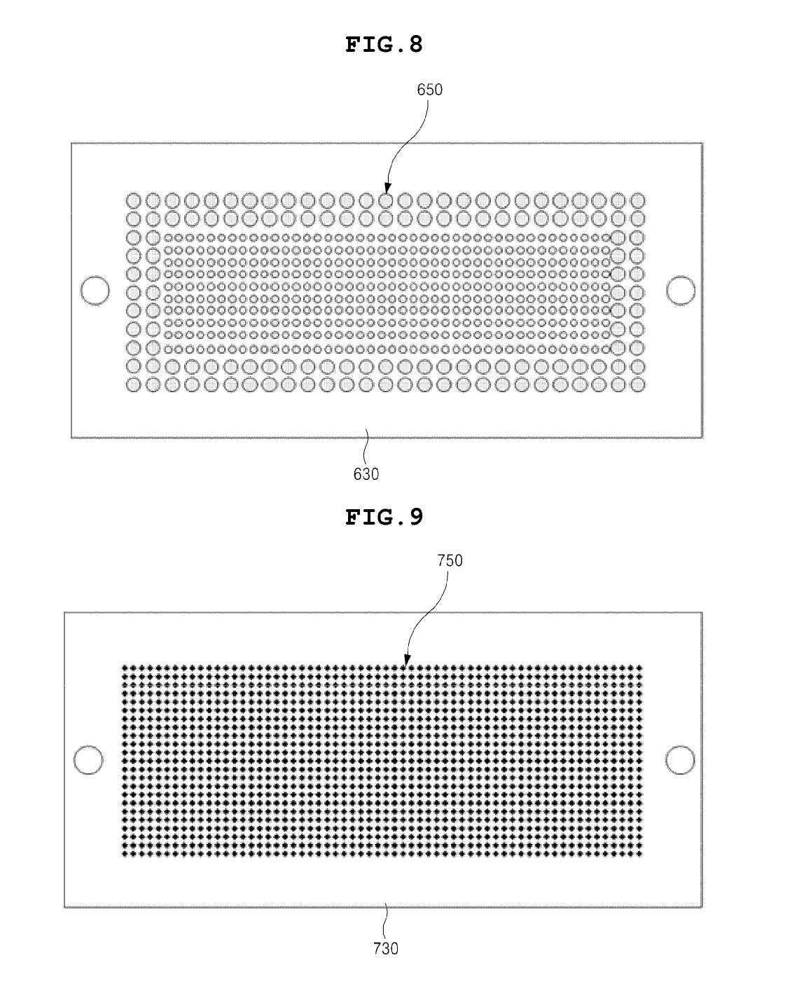

FIG. 8 shows a case in which first uneven patterns 650 are formed to have different shapes and different sizes over the entire surface region of a base plate 630.

FIG. 9 shows a case in which a first uneven pattern 750 has the same shape and same size over the entire surface region of a base plate 730.

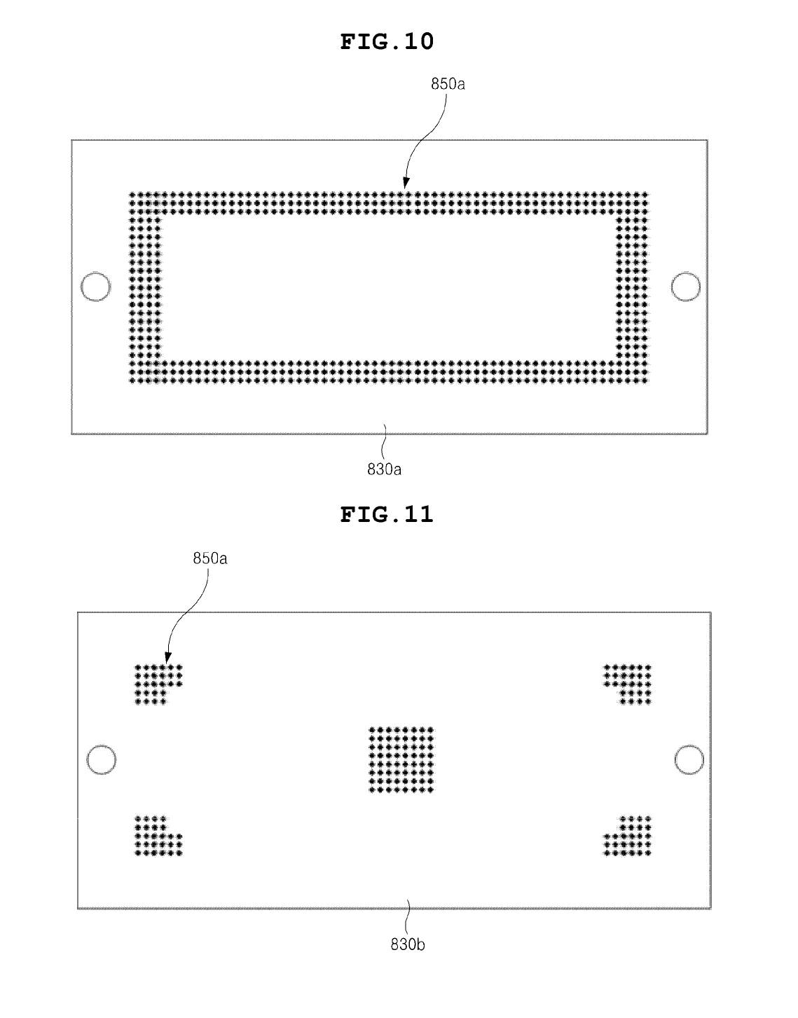

FIGS. 10 and 11 show cases in which first uneven patterns 850a and 850b are formed to have the same shape and same size over a part of the regions of base plates 830a and 830b, respectively.

When this structure is employed, a generation of a non-junction portion or a void can be restrained, and a crack propagation speed in the solder S1 junction region can be drastically lowered, in comparison to the related art.

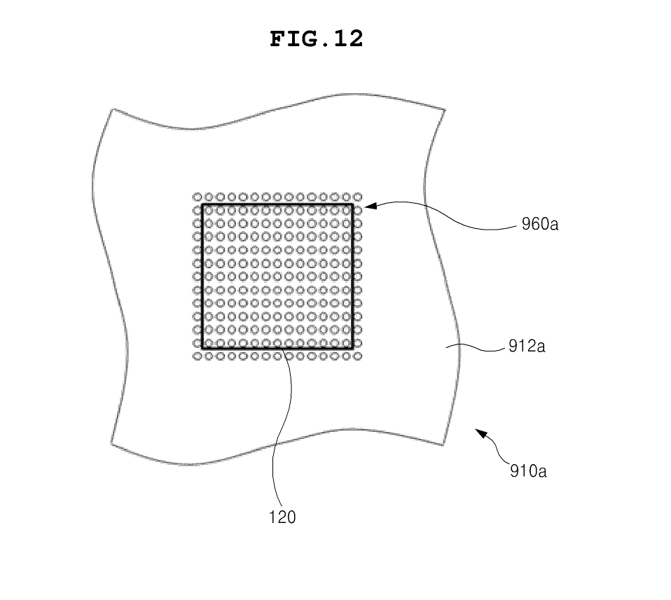

FIGS. 12 to 14 are modifications of second uneven patterns on second metal conductive tracks of substrates, respectively.

FIG. 12 shows a case in which a second uneven pattern 960a is formed on a surface of a second metal conductive track 912a of a substrate 910a to which the semiconductor element 120 is to be soldered. In this case, the second uneven pattern 960a is formed to have the same shape and same size on the entire surface region of the second metal conductive track 912a.

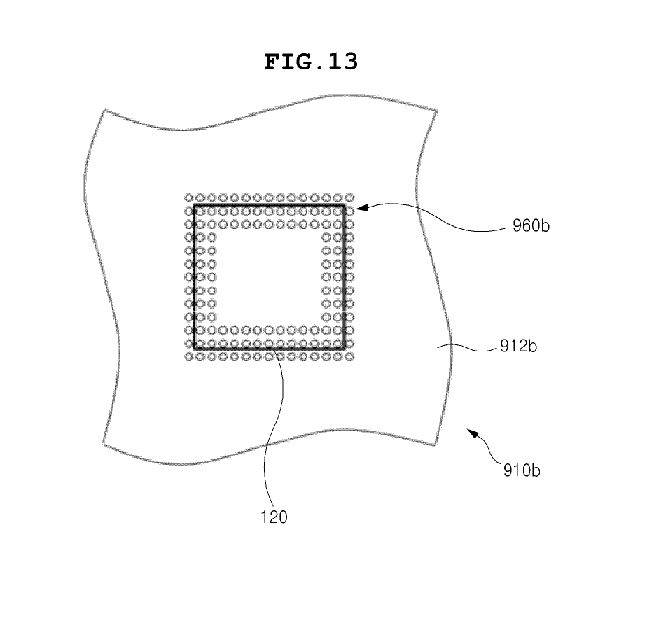

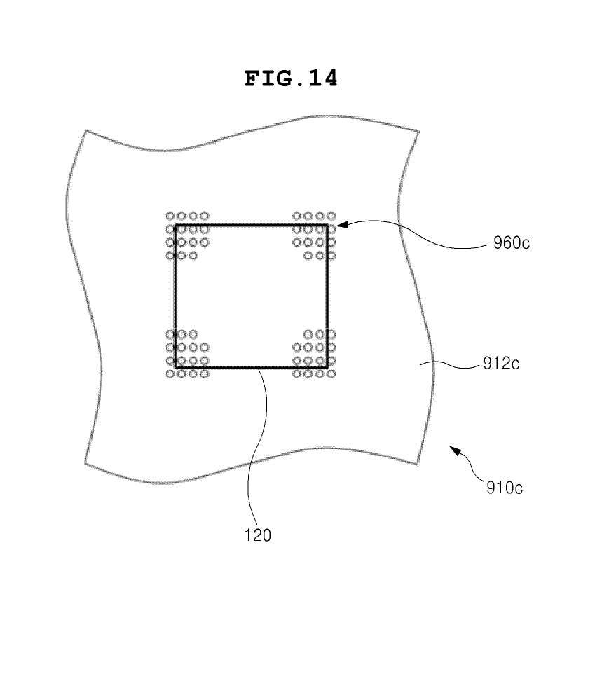

FIGS. 13 and 14 show cases in which second uneven patterns 960b and 960c are formed on surfaces of second metal conductive tracks 912b and 912c of substrates 910b and 910c to which the semiconductor element 120 is to be soldered. In this case, the second uneven patterns 960b and 960c are formed to have the same shape and same size over a part of the regions of the surfaces of the second metal conductive tracks 912b and 912c.

When this structure is employed, a generation of a non-junction portion or a void can be restrained, and a crack propagation speed in the solder S2 junction region can be drastically lowered, in comparison to the related art.

According to an embodiment of the present invention, a flux gas generated from a central region of a substrate can be easily discharged to the outside of the substrate during a soldering process performed between the substrate and a base plate, and thus, a generation of a non-junction portion or void can be restrained.

In addition, according to an embodiment of the present invention, since a crack propagation speed in a solder junction region can be drastically lowered due to structural stabilization, long-term reliability of the power semiconductor module can be obtained.

Although the embodiments of the present invention have been disclosed for illustrative purposes, it will be appreciated that the present invention is not limited thereto, and those skilled in the art will appreciate that various modifications, additions, and substitutions are possible, without departing from the scope and spirit of the invention.

Accordingly, any and all modifications, variations, or equivalent arrangements should be considered to be within the scope of the invention, and the detailed scope of the invention will be disclosed by the accompanying claims.

What is claimed is:

1. A power semiconductor module comprising:
a substrate having a first metal conductive track formed on one surface thereof; and
a base plate made of a metal and solder-joined to the substrate in the first metal conductive track region,
wherein a first uneven pattern is formed in the solder junction region formed between the substrate and the base plate.

2. The power semiconductor module as set forth in claim 1, wherein the first uneven pattern is formed on at least one of the first metal conductive track and the base plate.

3. The power semiconductor module as set forth in claim 1, wherein the first uneven pattern is formed to have different shapes and different sizes over the entire surface region of the first metal conductive track or the base plate.

4. The power semiconductor module as set forth in claim 1, wherein the first uneven pattern is formed to have different shapes and different sizes over a part of the regions of the surface of the first metal conductive track or the base plate.

5. The power semiconductor module as set forth in claim 1, wherein the first uneven pattern is formed to have the same shape and same size over the entire surface region of the first metal conductive track or the base plate.

6. The power semiconductor module as set forth in claim 1, wherein the first uneven pattern is formed over a part of the regions of the surface of the first metal conductive track or the base plate.

7. The power semiconductor module as set forth in claim 1, wherein a second metal conductive track is formed on the other surface of the substrate, a semiconductor element is mounted on the second metal conductive track, and
a second uneven pattern is formed in a solder junction region formed between the substrate and the semiconductor element.

8. The power semiconductor module as set forth in claim 7, wherein the second uneven pattern is formed on the second metal conductive track.

9. The power semiconductor module as set forth in claim 7, wherein the second uneven pattern is formed to have different shapes or sizes over the entire surface region of the surface of the second metal conductive track or over a part of the regions of the surface of the second metal conductive track.

10. The power semiconductor module as set forth in claim 7, wherein the second uneven pattern is formed to have the same shape and same size over the entire surface region of the surface of the second metal conductive track or over a part of the regions of the surface of the second metal conductive track.

11. The power semiconductor module as set forth in claim 1, wherein the first and second uneven patterns have a circular, quadrangular, or triangular shape, and are formed to be concave or convex on the corresponding surface.

12. The power semiconductor module as set forth in claim 1, wherein a heat sink is coupled to the base plate, and
the substrate is a direct bonded copper (DBC) ceramic substrate or a direct bonded aluminum (DBA) ceramic substrate.
